(19) United States
(12) Patent Application Publication
(10) Pub. No.: US 2019/0274216 A1
(43) Pub. Date: Sep. 5, 2019

(54) BOARD MODULE AND METHOD OF MANUFACTURING BOARD MODULE

(71) Applicant: FUJITSU LIMITED, Kawasaki-shi (JP)

(72) Inventors: TAKASHI KUBOTA, Chikuma (JP); Takayoshi Matsumura, Yokohama (JP); Naoaki Nakamura, Kawasaki (JP)

(73) Assignee: FUJITSU LIMITED, Kawasaki-shi (JP)

(21) Appl. No.: 16/278,765

(22) Filed: Feb. 19, 2019

(30) Foreign Application Priority Data
Mar. 2, 2018 (JP) 2018-037159

(51) Int. Cl. H05K 1/14; H05K 1/02; H01L 25/16

(52) U.S. Cl. CPC H05K 1/144; H05K 1/0201; H01L 25/167; H05K 1/0274

(57) ABSTRACT

A board module includes a first board having an inner wall that has a protrusion and defines a through hole. The board module includes a second board provided in the through hole and joined to the protrusion by using a resin. The board module includes a third board joined above and across the first board and the second board.

### CROSS-REFERENCE TO RELATED APPLICATION

This application is based upon and claims the benefit of priority of the prior Japanese Patent Application No. 2018-037159, filed on Mar. 2, 2018, the entire contents of which are incorporated herein by reference.

### FIELD

The embodiments discussed herein are related to a board module and a method of manufacturing a board module.

### BACKGROUND

As a method of mounting a chip component on a printed board, a method has been known which provides a through hole in the printed board, guides a conductive foil to both ends of the printed board, inserts a chip component having an electrode at both ends thereof into the through hole so that the chip component faces the conductive foil and is flush with the conductive foil, and solders the conductive foil and the electrode together. A method has also been known which attaches the chip component to an inner wall defining the through hole with an adhesive to temporarily fix the chip component to the through hole.

Also, a method has been known which accommodates an electronic component in the through hole provided in the board, fills the through hole, in which the electronic component is accommodated, with an adhesive, and then cures the adhesive.

Related techniques are disclosed in, for example, Japanese Laid-open Patent Publication No. 58-173884 and Japanese Laid-open Patent Publication No. 2002-076268.

### SUMMARY

According to an aspect of the present invention, provided is a board module. The board module includes a first board having an inner wall that has a protrusion and defines a through hole. The board module includes a second board provided in the through hole and joined to the protrusion by using a resin. The board module includes a third board joined above and across the first board and the second board.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are views illustrating an example of a board module;

FIGS. 2A to 2E are views illustrating an example of a method of forming the board module;

FIGS. 3A and 3B are explanatory views of a process of supplying a resin to form the board module;

FIGS. 4A and 4B are views illustrating an example of a board module according to a first embodiment;

FIGS. 5A to 5C are views illustrating an example of a method of forming the board module according to the first embodiment;

FIGS. 6A and 6B are first explanatory views of an example of an optical module according to a second embodiment;

FIGS. 7A and 7B are second explanatory views of an example of the optical module according to the second embodiment;

FIG. 8 is a view illustrating an example of a board module according to the second embodiment;

FIGS. 9A to 9C are views illustrating an example of a method of forming the board module according to the second embodiment;

FIGS. 10A and 10B are explanatory views of a first example of chip position control according to the second embodiment;

FIGS. 11A to 11C are explanatory views of a second example of the chip position control according to the second embodiment;

FIGS. 12A to 12C are explanatory views of a third example of the chip position control according to the second embodiment;

FIGS. 13A to 13C are views illustrating a configuration example of a circuit board according to the second embodiment;

FIGS. 14A to 14C are explanatory views of a positional relationship between a protrusion provided on the circuit board according to the second embodiment and a connecting portion of a heat dissipation member;

FIGS. 15A to 15C are views illustrating a first example of a method of forming a board module according to a third embodiment; and

FIGS. 16A to 16C are views illustrating a second example of the method of forming the board module according to the third embodiment.

### DESCRIPTION OF EMBODIMENTS

In the case of a board module which is formed by using a method which disposes a separate board in a through hole provided in the board and fixes the disposed board with a resin which is an adhesive, a width of a gap between the board and an inner wall that defines the through hole is not uniform if there is a relative positional deviation between the through hole and the board disposed in the through hole. In the case in which the width of the gap is not uniform, there is concern that the costs required to manufacture the board module are increased because the amount of a resin to be supplied is adjusted in accordance with the width of the gap, or quality of the board module deteriorates because the amount of a resin is excessive or deficient in accordance with points at which the width varies when a predetermined amount of a resin is supplied.

First, an example of a board module will be described.

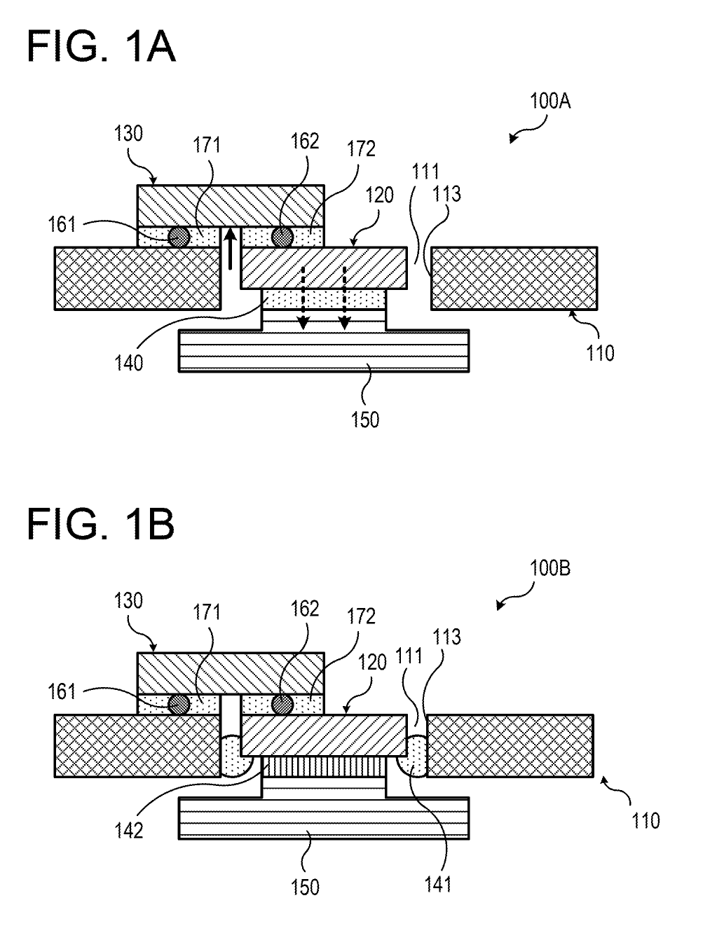

FIGS. 1A and 1B are views illustrating an example of the board module. FIGS. 1A and 1B schematically illustrate main-part cross-sectional views of an example of the board module, respectively.

A board module 100A illustrated in FIG. 1A includes a board 110 provided with a through hole 111, a board 120 disposed in the through hole 111, and a board 130 disposed above and across the board 110 and the board 120. The board module 100A illustrated in FIG. 1A further includes a heat dissipation member 150 which is joined to a lower portion of the board 120 in the through hole 111 by using a resin 140.

For example, a circuit board such as a printed board is used as the board 110 provided with the through hole 111. For example, a semiconductor chip, a semiconductor package on which a semiconductor chip is mounted, a chip component such as a condenser, or a circuit board such as a printed board is used as the board 120 disposed in the through hole 111 provided in the board 110. Similarly, for example, a semiconductor chip, a semiconductor package, a chip component, or a circuit board is used as the board 130 disposed above and across the board 110 and the board 120. Various types of resin materials having adhesiveness are used as the resin 140 that joins the board 120 and the heat dissipation member 150 together. The resin 140 is also referred to as an “underfill.” A material (e.g., copper (Cu)) having a comparatively high thermal conductivity is used as the heat dissipation member 150.

The board 110 and the board 130 are electrically and mechanically connected to each other by a bump 161 such as solder, and the connection is reinforced by a resin 171 provided between the board 110 and the board 130. The board 120 and the board 130 are electrically and mechanically connected to each other by a bump 162 such as solder, and the connection is reinforced by a resin 172 provided between the board 120 and the board 130. Various types of resin materials having adhesiveness are used as the resin 171 and the resin 172. Each of the resin 171 and the resin 172 is also referred to as an “underfill.”

In the board module 100A illustrated in FIG. 1A, the board 120 disposed in the through hole 111 provided in the board 110 is retained by the board 130 disposed above and across the board 110 and the board 120 and electrically and mechanically connected to each of the board 110 and the board 120. Here, for example, when the board 120 retained by the board 130 is joined to the heat dissipation member 150 by using the resin 140, and the resin 140 is shrunk along with the curing (curing shrinkage), force (dotted arrows in FIG. 1A), which pulls the board 120 toward the heat dissipation member 150, is applied. When this force is applied, there is concern that a joint portion between the board 120 and the board 130 or a joint portion between the board 130 and the board 110 is damaged, stress (a solid arrow in FIG. 1A) is concentrated at an intermediate portion of the board 130 that bridges the board 120 and the board 110, and the board 130 is damaged.

Therefore, a board module 100B illustrated in FIG. 1B is considered.

In the board module 100B illustrated in FIG. 1B, lateral edge portions of the board 120 disposed in the through hole 111 provided in the board 110 are joined, by using the resin 141, to an inner wall 113 that defines the through hole 111. Various types of resin materials having adhesiveness are used as the resin 141. The resin 141 is also referred to as a “side-fill.” In addition, in the board module 100B illustrated in FIG. 1B, the heat dissipation member 150 is joined to the lower portion of the board 120 by using a thermal interface material (TIM) 142 such as a thermal sheet.

To form the board module 100B, before joining the heat dissipation member 150 by using the TIM 142 having comparatively small curing shrinkage, the lateral edge portions of the board 120 retained, by the board 130, in the through hole 111 provided in the board 110 are joined, by the resin 141, to the inner wall 113 that defines the through hole 111.

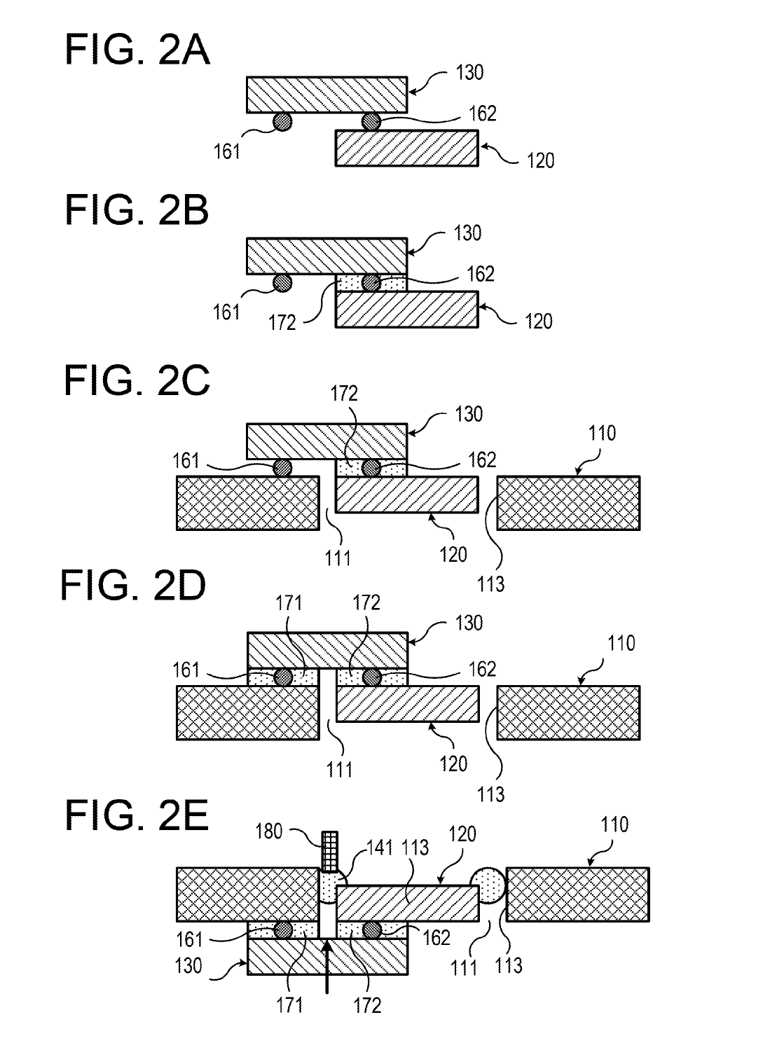

FIGS. 2A to 2E are views illustrating an example of a method of forming the board module. FIGS. 2A to 2E schematically illustrate main-part cross-sectional views of a process of an example of the method of forming the board module illustrated in FIG. 1B.

To form the board module 100B, for example, first, as illustrated in FIG. 2A, the one bump 162 mounted on the board 130 is joined to the board 120, and the board 130 and the board 120 are electrically and mechanically connected to each other. Thereafter, as illustrated in FIG. 2B, the resin 172 is supplied between the board 130 and the board 120 joined together by the bump 162, and thus the connection between the board 130 and the board 120 is reinforced.

Next, as illustrated in FIG. 2C, the board 130, which is connected to the board 120 by the bump 162 and the resin 172, is mounted on the board 110. At this time, the board 120 is inserted into the through hole 111 provided in the board 110, the other bump 161 mounted on the board 130 is joined to the board 110, and the board 130 and the board 110 are electrically and mechanically connected to each other. Thereafter, as illustrated in FIG. 2D, the resin 171 is supplied between the board 130 and the board 110 joined together by the bump 161, and thus the connection between the board 130 and the board 110 is reinforced. Therefore, the board 120 is retained in the through hole 111 provided in the board 110 by the board 130 connected to the board 110 and the board 120.

Next, as illustrated in FIG. 2E, the resin 141 is supplied, by using a nozzle 180, between the board 120 and the inner wall 113, which defines the through hole 111 provided in the board 110, from a surface of the board 120 which is opposite to the board 130, and then the resin 141 is cured. Thereafter, as illustrated in FIG. 1B, the heat dissipation member 150 is joined to the board 120 by using the TIM142.

In the board module 100B formed by using the aforementioned method, the lateral edge portions of the board 120 are joined, by the resin 141, to the inner wall 113, which defines the through hole 111 provided in the board 110, before the heat dissipation member 150 is joined by the TIM142 (FIG. 2E). For this reason, stress is suppressed from being concentrated at the board 130 when the board 120 and the heat dissipation member 150 are joined together. However, in this method, the resin 141 experiences the curing shrinkage when the lateral edge portions of the board 120 are joined, by the resin 141, to the inner wall 113 that defines the through hole 111 provided in the board 110 (FIG. 2E), and as a result, there is concern that stress is concentrated at the board 130 (a solid arrow in FIG. 2E) and the board 130 is damaged.

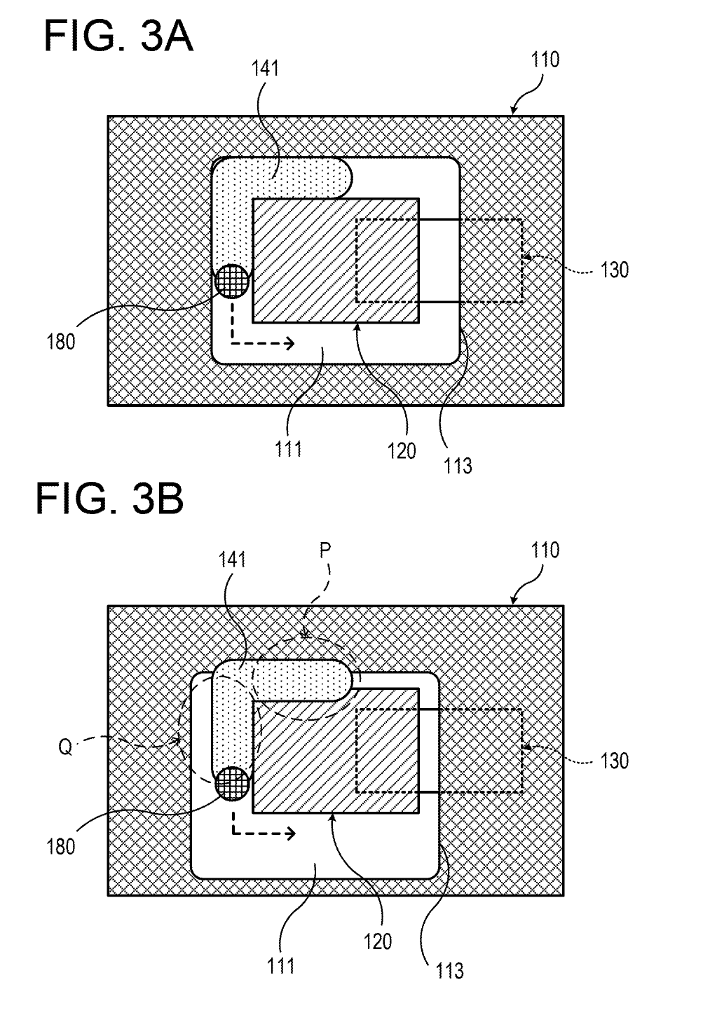

In this method, if there is a relative positional deviation between the through hole 111 provided in the board 110 and the board 120 disposed in the through hole 111, there is concern that problems occur in terms of costs and quality. This will be described with reference to FIGS. 3A and 3B.

FIGS. 3A and 3B are explanatory views of a process of supplying a resin to form the board module. FIGS. 3A and 3B schematically illustrate main-part top plan views of an example of a process of supplying a resin, respectively.

For example, the board 120 (the board 120 connected to the board 130) may be disposed with comparatively high position precision with respect to the board 110 by using an electronic component mounting technology. Meanwhile, in a case where the through hole 111, which allows the board 120 to be disposed therein, is formed in the board 110 by using a machining technology such as drilling, it is difficult to form the through hole 111 with high position precision in the board 110, and a position of the formed through hole 111 may be varied. In order to try to form the through hole 111 with high position precision, manufacturing costs of the board module 100B are increased.

Now, as illustrated in FIG. 3A, it is assumed that the through hole 111 provided in the board 110 is precisely formed at a predetermined position at which there is no positional deviation between the through hole 111 and the board 120 inserted into the through hole 111. In this case, a gap between the inserted board 120 and the inner wall 113 that defines the through hole 111 becomes uniform or substantially uniform, and thus the uniform or substantially uniform amount of the resin 141 may be supplied along a circumference of the board 120 by supplying a predetermined amount of the resin 141 along the gap from the nozzle 180. A resin having comparatively high viscosity is used as the resin 141 to be supplied, so that the resin 141 may remain in the gap between the circumference of the board 120 and the inner wall 113 that defines the through hole 111.

Meanwhile, as illustrated in FIG. 3B, it is assumed that the through hole 111 provided in the board 110 is not precisely formed at a predetermined position at which there is no positional deviation between the through hole 111 and the board 120 inserted into the through hole 111. In this case, the gap between the inserted board 120 and the inner wall 113 that defines the through hole 111 becomes non-uniform. The nozzle 180 may interfere with the inner wall 113, which defines the through hole 111, when the resin 141 is supplied along the gap from the nozzle 180. In addition, when a predetermined amount of the resin 141 is supplied from the nozzle 180, a surplus amount of the resin 141 may be supplied into the gap at a point P at which the gap is narrow. The amount of the resin 141, which is required and sufficient to fill the gap, cannot be supplied at a point Q at which the gap is wide, the board 120 and the inner wall 113, which defines the through hole 111, cannot be joined together, or the resin 141 may droop along a side surface of the board 120 to the surface of the opposite side (a side to which the board 130 is connected). In order to control the amount of the resin 141 to be supplied in accordance with the width of the gap, manufacturing costs of the board module 100B are increased.

In the configuration such as the board modules 100A and 100B described above, it may be difficult to implement the board module having high quality with low costs.

Here, in consideration of this situation, configurations implemented by the following embodiments are adopted.

### First Embodiment

First, a first embodiment will be described.

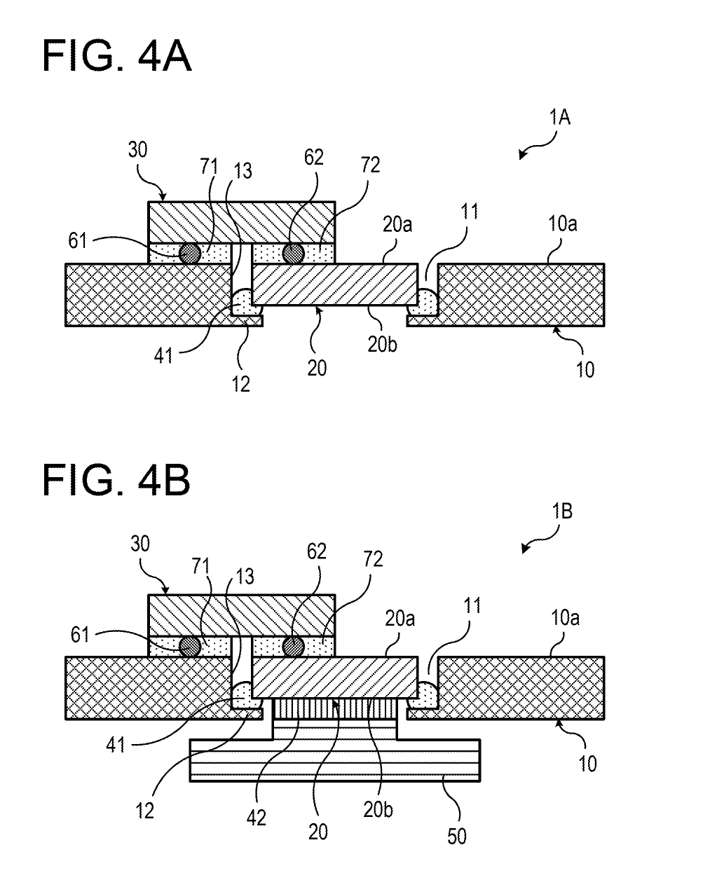

FIGS. 4A and 4B are views illustrating an example of a board module according to the first embodiment. FIGS. 4A and 4B schematically illustrate main-part cross-sectional views of an example of the board module, respectively.

A board module 1A illustrated in FIG. 4A includes a board 10 provided with a through hole 11 defined by an inner wall 13 having a protrusion 12, a board 20 disposed above the protrusion 12 in the through hole 11 via a resin 41, and a board 30 disposed above and across the board 10 and the board 20. The through hole 11 may be defined by a plurality of inner walls 13. Hereinafter, for simplicity, “the inner wall 13” may refer to the plurality of inner walls 13 that define the through hole 11. The inner wall 13 may have a plurality of protrusions 12. Hereinafter, for simplicity, “the protrusion 12” may refer to the plurality of protrusions 12 of the inner wall 13.

For example, various types of circuit boards such as a printed board, a package board, an interposer, a motherboard, and a daughter board may be used as the board 10.

The through hole 11, which has an opening size that enables the board 20 to be inserted into the through hole 11, is provided in the board 10. The protrusion 12, which extend toward the inside of the through hole 11, is provided on the inner wall 13 that defines the through hole 11. The protrusion 12 has a length that extends from the inner wall 13, which defines the through hole 11, toward the inside of the through hole 11 to a position at which a tip portion of the protrusion 12 overlaps a lower portion of the board 20 disposed in the through hole 11. A thickness of the protrusion 12 is not limited as long as the tip portion of the protrusion 12 is positioned below the board 20 when an upper surface 20a of the board 20 disposed in the through hole 11 is positioned at a predetermined position with respect to an upper surface 10a of the board 10, for example, at a position at which the upper surfaces 20a and 10a of the substrates 20 and 10 are disposed on the same plane.

The protrusion 12 may be formed as a part of the board 10 or may be formed by mounting a component, which is prepared separately, to the inner wall 13 that defines the through hole 11 provided in the board 10.

For example, the following method is used to form the protrusion 12 as a part of the board 10. That is, a hole portion, which corresponds to an upper side from the protrusion 12, is formed by drilling with a depth that does not penetrate the board 10, and a hole portion defined by the protrusion 12 is formed by drilling with a depth that penetrates the board 10. In this case, any one of the drilling with the depth that does not penetrate the board 10 and the drilling with the depth that penetrates the board 10 may be performed first prior to the other.

For example, the following method is used to form the protrusion 12 by mounting the separately prepared component on the inner wall 13 that defines the through hole 11 provided in the board 10. That is, a hole portion, which penetrates the board 10, is formed by drilling, and a component, which is separately prepared by a technique such as machining or injection molding, is mounted on the inner wall 13, which defines the hole portion, by a technique such as adhesion, welding, mating, or threaded-engaging.

For example, a semiconductor chip, a semiconductor package, a chip component, or a circuit board may be used as the board 20. Various types of semiconductor chips including a semiconductor element such as a transistor or various types of semiconductor chips including an optical element such as a light receiving element, a light emitting element, an optical waveguide, and an optical modulator are used as the semiconductor chip. Various types of semiconductor packages in which a semiconductor chip is mounted on a package board or the like are used as the semiconductor package. Various types of chip components such as a condenser, an inductor, and a resistor are used as the chip component. Various types of circuit boards such as a printed board, a package board, an interposer, and a daughter board are used as the circuit board.

The board 20 is disposed in the through hole 11 provided in the board 10 and joined, by using the resin 41, to the protrusion 12 provided on the inner wall 13 that defines the through hole 11. The board 20 is joined, by using the resin 41, to the protrusion 12 such that the upper surface 20a of the board 20 is positioned at a predetermined position with respect to the upper surface 10a of the board 10, that is, for example, as illustrated in FIG. 4A, a position at which the upper surfaces 20a and 10a of the boards 20 and 10 are positioned on the same plane.

Various types of resin materials such as thermosetting resin, thermoplastic resin, and photocurable resin having adhesiveness are used as the resin 41. For example, thermosetting resin such as epoxy resin, phenol resin, and polyimide resin, thermoplastic resin such as polyethylene-terephthalate resin, acrylic resin, and polyamide resin, epoxy-based or acrylate-based ultraviolet curable resin, and the like are used as the resin 41. The resin 41 may contain a conductive or insulating filler. The resin 41 is also referred to as a “side-fill.”

For example, a semiconductor chip, a semiconductor package, a chip component, or a circuit board may be used as the board 30. Various types of semiconductor chips including a semiconductor element such as a transistor or various types of semiconductor chips including an optical element such as a light receiving element, a light emitting element, an optical waveguide, and an optical modulator are used as the semiconductor chip. Various types of semiconductor packages in which a semiconductor chip is mounted on a package board or the like are used as the semiconductor package. Various types of chip components such as a condenser, an inductor, and a resistor are used as the chip component. Various types of circuit boards such as a printed board, a package board, an interposer, and a daughter board are used as the circuit board.

The board 30 is disposed above and across the board 10 and the board 20. The board 30 is electrically and mechanically connected to the board 10 by a bump 61 such as solder and electrically and mechanically connected to the board 20 by a bump 62 such as solder. The connection between the board 30 and the board 10 by the bump 61 is reinforced by a resin 71 provided between the board 30 and the board 10, and the connection between the board 30 and the board 20 by the bump 62 is reinforced by a resin 72 provided between the board 30 and the board 20.

Various types of resin materials such as thermosetting resin, thermoplastic resin, and photocurable resin having adhesiveness are used as the resin 71 and the resin 72. For example, thermosetting resin such as epoxy resin, phenol resin, and polyimide resin, thermoplastic resin such as polyethylene-terephthalate resin, acrylic resin, and polyamide resin, epoxy-based or acrylate-based ultraviolet curable resin, and the like are used as the resin 71 and the resin 72. Each of the resin 71 and the resin 72 may contain an insulating filler. The resin 71 and the resin 72 may be the same type or different types. Each of the resin 71 and the resin 72 is also referred to as an “underfill.”

The bumps 61 and 62 may be examples of joint portions that electrically and mechanically connect the board 30 to the board 10 and the board 20, and a solder bump, a pillar electrode such as Cu, or a combination thereof may be used as the joint portion.

A board module 18 illustrated in FIG. 4B differs from the board module 1A in that a heat dissipation member 50 is joined, by using a TIM 42 such as a thermal sheet or a thermal grease, to a lower surface 20b of the board 20 joined, by using the resin 41, to the protrusion 12 in the through hole 11 provided in the board 10.

The heat dissipation member 50 of the board module 18 is made of a material, such as copper (Cu), aluminum (Al), or carbon (C) having a comparatively high thermal conductivity. For example, the configuration of the board module 18 illustrated in FIG. 4B is adopted in a case where one or both of the board 20 and the board 30 generate heat while operating. The heat generated in the board 20 or the heat transferred to the board 20 is transferred to the heat dissipation member 50 via the TIM 42 and then dissipated from the heat dissipation member 50, and thus, overheating of the board 20 and the board 30 and damage or deterioration in performance caused by the overheating are suppressed.

According to the board modules 1A and 1B, the board 20 is joined, by using the resin 41, to the protrusion 12 in the through hole 11 provided in the board 10, and as a result, it is possible to implement the board modules 1A and 1B having high quality with low costs even though position precision of the through hole 11 provided in the board 10 is not high.

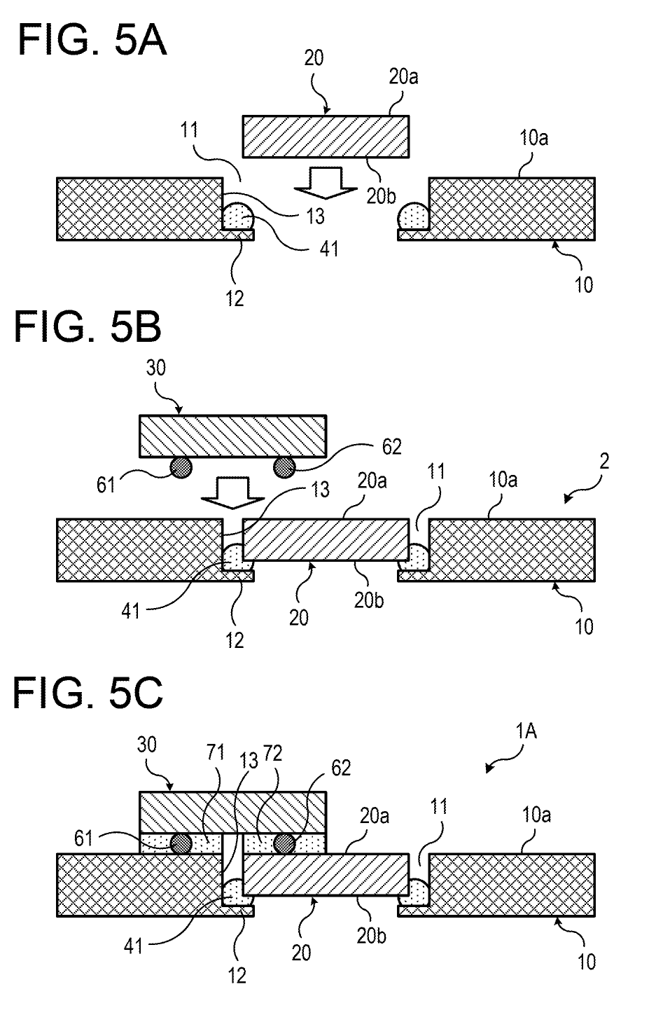

FIGS. 5A to 5C are views illustrating an example of a method of forming the board module according to the first embodiment. FIGS. 5A to 5C schematically illustrate main-part cross-sectional views of processes. Here, a method of forming the board module 1A illustrated in FIG. 4A will be described as an example.

To form the board module 1A, first, as illustrated in FIG. 5A, the board 10 having the through hole 11 defined by the inner wall 13 having the protrusion 12 and the board 20 disposed in the through hole 11 provided in the board 10 are prepared. Further, the resin 41 is supplied onto the protrusion 12 provided on the prepared board 10 by using a supply device such as a dispenser (nozzle) (not illustrated). The prepared board 20 is inserted into the through hole 11 in which the resin 41 is supplied onto the protrusion 12.

The board 20, which is inserted into the through hole 11, is controlled to a position at which the upper surface 20a of the board 20 is positioned at a predetermined position with respect to the upper surface 10a of the board 10, that is, for example, as illustrated in FIG. 5B, a position at which the upper surfaces 20a and 10a of the boards 20 and 10 are positioned on the same plane. The resin 41 is cured in a state where the upper surface 20a of the board 20 is controlled to a predetermined position. Therefore, a structure 2 in which the board 20 is joined to the board 10 (the protrusion 12 provided on the board 10) by using the resin 41 is formed. As illustrated in FIG. 5B, the board 30, which is prepared by mounting the bumps 61 and 62, is mounted on the formed structure 2.

As illustrated in FIG. 5C, the board 30 is mounted above and across the board 10 and the board 20. The one bump 61 mounted on the board 30 is joined to the board 10, and the other bump 62 mounted on the board 30 is joined to the board 20, so that the board 30 is electrically and mechanically connected to the board 10 and the board 20. Thereafter, as illustrated in FIG. 5C, the resin 71 is supplied between the board 30 and the board 10 joined together by the bump 61, and the resin 72 is supplied between the board 30 and the board 20 joined together by the bump 62, so that the connection between the board 30 and the board 10 and the connection between the board 30 and the board 20 are reinforced.

The board module 1A illustrated in FIG. 4A is formed by the method illustrated in FIGS. 5A to 5C.

The heat dissipation member 50 is joined to the lower surface 20b of the board 20 by using the TIM 42 after the board module 1A is formed, and thus, the board module 18 illustrated in FIG. 4B is formed.

In the method illustrated in FIGS. 5A to 5C, the resin 41 is supplied onto the protrusion 12 provided on the board 10, and the board 20 inserted into the through hole 11 is joined to the protrusion 12 by using the resin 41. For this reason, even though the position precision of the through hole 11 provided in the board 10 is not high, the problem described with reference to FIGS. 2E and 3B and caused by a variation of the width of the gap between the board 20 and the inner wall 13 that defines the through hole 11, that is, interference with the nozzle, excess or deficiency of the resin 41, and drooping of the resin 41 may be suppressed. Therefore, it is possible to obtain the board modules 1A and 18 having high quality.

In the method illustrated in FIGS. 5A to 5C, after the board modules 1A and 18 having high quality are obtained, it is not necessary to form the through hole 11 in the board 10 with high position precision, and it is not necessary to control the amount of the resin 41 in accordance with the width of the gap between the board 20 and the inner wall 13 that defines the through hole 11. For this reason, it is possible to suppress an increase in manufacturing costs of the board modules 1A and 1B.

In addition, it is possible to reduce the number of processes in the method illustrated in FIGS. 5A to 5C in comparison with the method illustrated in FIGS. 2A to 2E. For this reason, it is possible to reduce manufacturing costs of the board modules 1A and 1B.

In the method illustrated in FIGS. 5A to 5C, the board 20 is joined to the protrusion 12 provided on the board 10 by using the resin 41, and then the board 30 is mounted above and across the board 10 and the board 20. For this reason, it is possible to suppress concentration of stress at the board 30 caused by the curing shrinkage of the resin 41, and damage to the board 30 caused by the concentration of stress, as described with reference to FIG. 2E.

According to the board modules 1A and 1B having the aforementioned configuration and the method of forming the board modules 1A and 1B, it is possible to implement the board modules 1A and 1B having high quality with low costs.

### Second Embodiment

Next, a second embodiment will be described. Here, an application example of the board modules 1A and 1B will be described as the second embodiment.

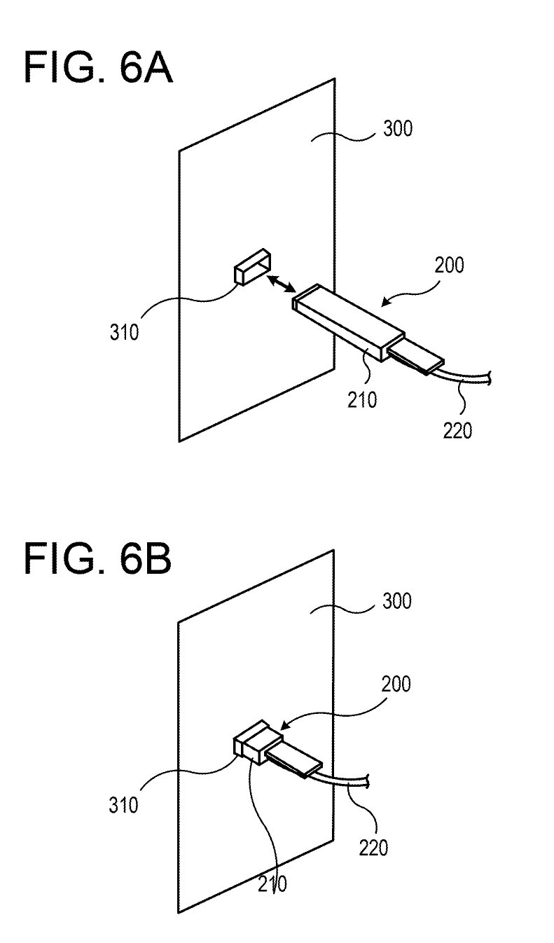

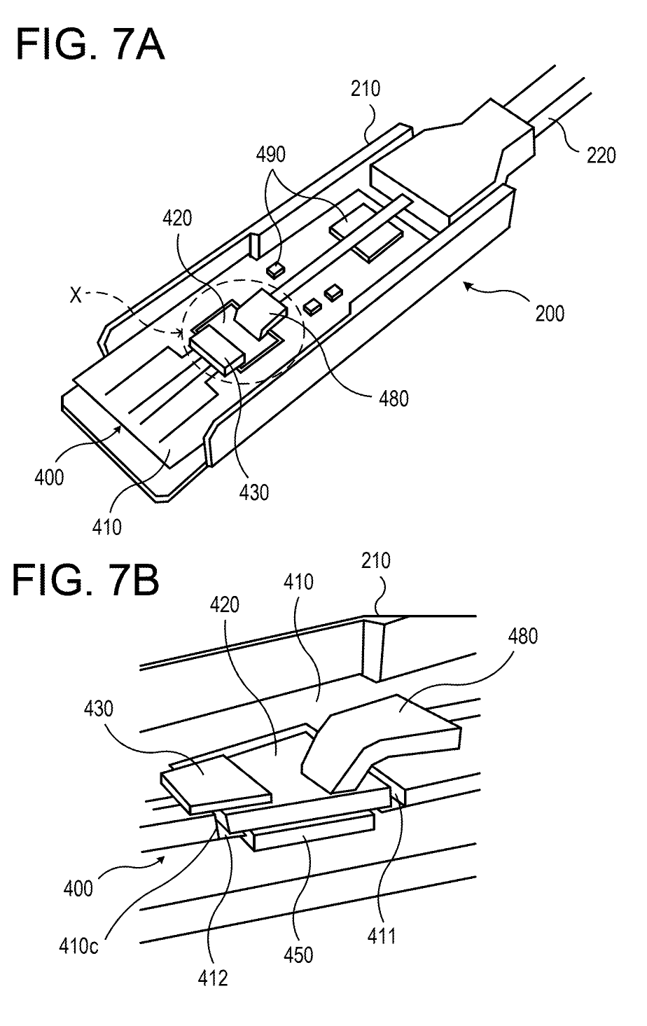

FIGS. 6A and 6B and FIGS. 7A and 7B are explanatory views of an example of an optical module according to the second embodiment. FIGS. 6A and 6B schematically illustrate main-part perspective views for explaining an example of a usage state (insertion and extraction) of the optical module. FIG. 7A schematically illustrates an exploded main-part perspective view of the optical module, and FIG. 7B schematically illustrates an enlarged main-part cross-sectional perspective view of a portion X in FIG. 7A.

As an example, a usage example of an optical module 200 having a quad small form-factor pluggable (QSFP) standard is illustrated in FIGS. 6A and 6B. The optical module 200 may be inserted into and extracted from a cage 310 provided on an electronic apparatus 300 such as a server. FIG. 6A illustrates a state before the optical module 200 is inserted into the cage 310 and a state after the optical module 200 is removed from the cage 310, and FIG. 6B illustrates a state after the optical module 200 is inserted into the cage 310.

As illustrated in FIGS. 7A and 7B, the optical module 200 includes a board module 400 mounted in a casing 210. In addition, the structure (optical module 200) in which the board module 400 is mounted in the casing 210 is referred to as the “board module.”

The board module 400 includes a circuit board 410, a silicon photonics (Si-Ph) chip 420, and a control chip 430. In addition, the circuit board 410 is an example of the board 10 described in the first embodiment, the Si-Ph chip 420 is an example of the board 20 described in the first embodiment, and the control chip 430 is an example of the board 30 described in the first embodiment.

The circuit board 410 is provided with a through hole 411 defined by an inner wall 410c having a protrusion 412. The Si-Ph chip 420 is disposed in the through hole 411 provided in the circuit board 410 and disposed on the protrusion 412 provided in the through hole 411. The Si-Ph chip 420 includes optical elements such as a light receiving element, a light emitting element, an optical waveguide, and an optical modulator, and wires through which power and signals are transmitted. An optical connector 480, which extends from a cable 220 of the optical module 200, is connected to the optical element of the Si-Ph chip 420. The control chip 430 is disposed above and across the circuit board 410 and the Si-Ph chip 420. In addition to the control chip 430, other components 490 (electronic components such as a semiconductor chip and a chip component or an optical component) may be mounted on the circuit board 410. A heat dissipation member 450 is disposed below the Si-Ph chip 420. The heat dissipation member 450 may be a separate member with respect to the casing 210 of the optical module 200, or may be a part of the casing 210.

The board module 400 will be further described.

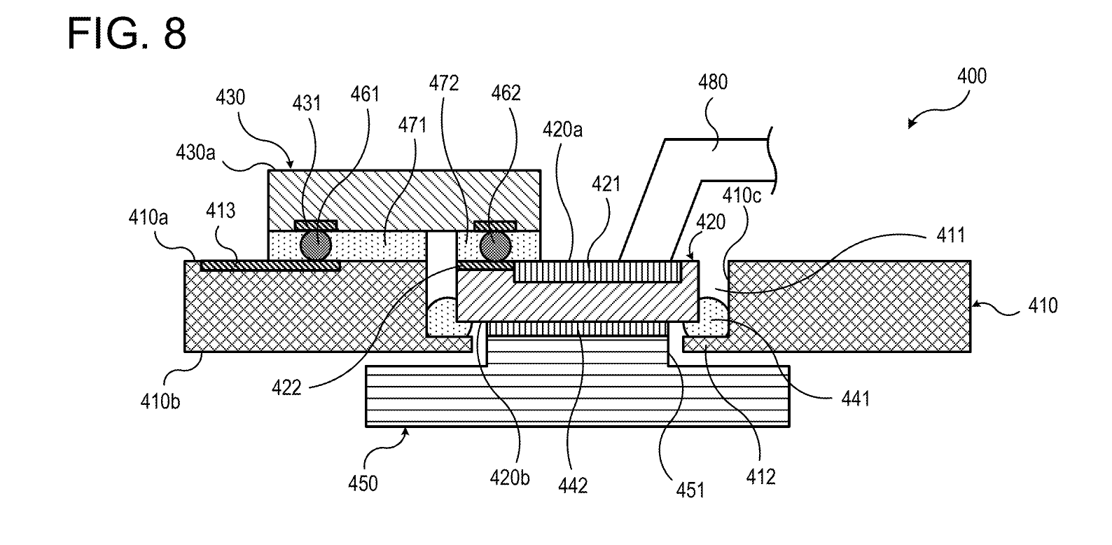

FIG. 8 is a view illustrating an example of the board module according to the second embodiment. FIG. 8 schematically illustrates a main-part cross-sectional view of an example of the board module.

As illustrated in FIG. 8, the board module 400 includes the circuit board 410 provided with the through hole 411 defined by the inner wall 410c having the protrusion 412, and the Si-Ph chip 420 disposed on the protrusion 412 in the through hole 411 via the resin 441. The board module 400 further includes the control chip 430 disposed above and across the circuit board 410 and the Si-Ph chip 420. The optical connector 480 is disposed on an upper surface 420a of the Si-Ph chip 420, and the heat dissipation member 450 is disposed on a lower surface 420b of the Si-Ph chip 420 via a TIM 442.

For example, a printed board is used as the circuit board 410. A wire 413, which is made of various types of conductor materials such as Cu and has a predetermined pattern shape, is provided on the circuit board 410. Here, the wire 413 provided on the upper surface 410a of the circuit board 410 is illustrated as an example, but a wire having a predetermined pattern shape may also be provided on the lower surface 410b and the inside of the circuit board 410 in addition to the upper surface 410a.

The through hole 411 provided in the circuit board 410 has an opening size that enables the Si-Ph chip 420 to be inserted into the through hole 411. A length of the protrusion 412 provided in the through hole 411 (a length that extends toward the inside of the through hole 411 from the inner wall 410c that defines the through hole 411) is a length that allows a tip portion of the protrusion 412 to be at least positioned to overlap a lower portion of the Si-Ph chip 420 disposed in the through hole 411.

The protrusion 412 may be formed as a part of the circuit board 410, or may be formed by mounting a component, which is prepared separately, to the inner wall 410c that defines the through hole 411 provided in the circuit board 410.

For example, the following method is used in a case where the protrusion 412 is formed as a part of the circuit board 410. That is, a hole portion, which corresponds to an upper side from the protrusion 412, is formed by drilling with a depth that does not penetrate the circuit board 410, and a hole portion, which corresponds to a portion between the facing protrusion 412, is formed by drilling with a depth that penetrates the circuit board 410. In this case, any one of the drilling with the depth that does not penetrate the circuit board 410 and the drilling with the depth that penetrates the circuit board 410 may be performed first prior to the other.

For example, the following method is used in a case where the protrusion 412 is formed by mounting the separately prepared component on the inner wall 410c that defines the through hole 411 provided in the circuit board 410. That is, a hole portion, which penetrates the circuit board 410, is formed by drilling, and a component, which is separately prepared by a technique such as machining or injection molding, is mounted on the inner wall, which defines the formed hole portion, by a technique such as adhesion, welding, mating, or threaded-engaging.

The Si-Ph chip 420 is disposed on the protrusion 412 provided in the through hole 411 provided in the circuit board 410 via the resin 441, and the Si-Ph chip 420 is joined to the protrusion 412 (the circuit board 410 having the protrusion 412) by using the resin 441. The Si-Ph chip 420 is joined to the protrusion 412 by using the resin 441 such that the upper surface 420a of the Si-Ph chip 420 is positioned at a predetermined position with respect to the upper surface 410a of the circuit board 410, that is, for example, as illustrated in FIG. 8, a position at which the upper surfaces 420a and 410a of the Si-Ph chip 420 and the circuit board 410 are positioned on the same plane.

Various types of resin materials such as thermosetting or photocurable resin materials are used as the resin 441. For example, thermosetting resin such as epoxy resin, phenol resin, and polyimide resin, thermoplastic resin such as polyethylene-terephthalate resin, acrylic resin, and polyamide resin, epoxy-based or acrylate-based ultraviolet curable resin, and the like are used as the resin 441. The resin 441 may contain a conductive or insulating filler.

The Si-Ph chip 420 is formed by using a silicon (Si) board or a silicon-on-insulator (SOI) board. The Si-Ph chip 420 includes an optical element unit 421 having an optical element such as a light receiving element, a light emitting element, an optical waveguide, or an optical modulator, and a wire 422 through which an electrical signal such as power, a control signal, or a photoelectric conversion signal is transmitted. The optical connector 480 is optically connected to the optical element unit 421.

The control chip 430 is disposed above and across the circuit board 410 and the Si-Ph chip 420. Various types of semiconductor chips are used as the control chip 430. The control chip 430 is electrically and mechanically connected to each of the wire 413 of the circuit board 410 and the wire 422 of the Si-Ph chip 420 by a bump 461 and a bump 462 such as solder mounted on an electrode 431. Electrical signals are transmitted between the control chip 430 and the circuit board 410 through the electrode 431, the bump 461, and the wire 413. Electrical signals are transmitted between the control chip 430 and the Si-Ph chip 420 through the electrode 431, the bump 462, and the wire 422.

For example, the control chip 430 transmits the electrical signal to the wire 422 of the Si-Ph chip 420 through the bump 462 and controls an operation (an operation of turning ON/OFF emitting light of the light emitting element, phase modulation of propagating light of the optical modulator, and the like) of the optical element unit 421 of the Si-Ph chip 420 through the wire 422. In addition, the electrical signal (a photoelectric conversion signal by the light receiving element and the like) may be transmitted from the Si-Ph chip 420 to the control chip 430 through the wire 422 and the bump 462.

The connection between the control chip 430 and the circuit board 410 through the bump 461 is reinforced by a resin 471 provided between the control chip 430 and the circuit board 410. The connection between the control chip 430 and the Si-Ph chip 420 through the bump 462 is reinforced by a resin 472 provided between the control chip 430 and the Si-Ph chip 420.

Various types of resin materials such as thermosetting or photocurable resin materials are used as the resin 471 and the resin 472. For example, thermosetting resin such as epoxy resin, phenol resin, and polyimide resin, thermoplastic resin such as polyethylene-terephthalate resin, acrylic resin, and polyamide resin, epoxy-based or acrylate-based ultraviolet curable resin, and the like are used as the resin 471 and the resin 472. Each of the resin 471 and the resin 472 may contain an insulating filler. The resin 471 and the resin 472 may be the same type or different types.

The bumps 461 and 462 may be examples of joint portions that electrically and mechanically connect the control chip 430 to the circuit board 410 and the Si-Ph chip 420, and a solder bump, a pillar electrode such as Cu, or a combination thereof may be used as the joint portion.

The Si-Ph chip 420 is thermally connected to the heat dissipation member 450 (a separate member with respect to the casing 210 of the optical module 200 or a part of the casing 210) disposed on the lower surface 420b of the Si-Ph chip 420 via the TIM 442. The heat dissipation member 450 has a connecting portion 451 having a size smaller in a plan view than a size of the inside of the protrusion 412 provided on the circuit board 410. The TIM 442 is interposed between the connecting portion 451 and the lower surface 420b of the Si-Ph chip 420, and the heat dissipation member 450 and the Si-Ph chip 420 are thermally connected to each other. In addition, the connecting portion 451 of the heat dissipation member 450 need not necessarily be inserted into the inside of the facing protrusion 412 on the circuit board 410.

Since the heat dissipation member 450 is provided on the lower surface 420b of the Si-Ph chip 420 via the TIM 442, the heat, which is generated in the control chip 430 and transferred to the Si-Ph chip 420, or the heat generated in the Si-Ph chip 420 is transferred to the heat dissipation member 450 through the TIM 442. The heat transferred to the Si-Ph chip 420 or the heat generated in the Si-Ph chip 420 is transferred to the heat dissipation member 450 and then dissipated from the heat dissipation member 450, and thus, overheating of the Si-Ph chip 420 and the control chip 430 and damage and deterioration in performance caused by the overheating are suppressed.

Although not illustrated, the heat dissipation member may be provided on the upper surface 430a of the control chip 430 via the TIM or the like, and the heat generated in the control chip 430 or the heat transferred to the control chip 430 may be dissipated by using the heat dissipation member.

In the board module 400 described above, the Si-Ph chip 420 is joined, by using the resin 441, to the protrusion 412 in the through hole 411 provided in the circuit board 410. For this reason, it is possible to implement the board module 400 having high quality with low costs even though position precision of the through hole 411 provided in the circuit board 410 is not high.

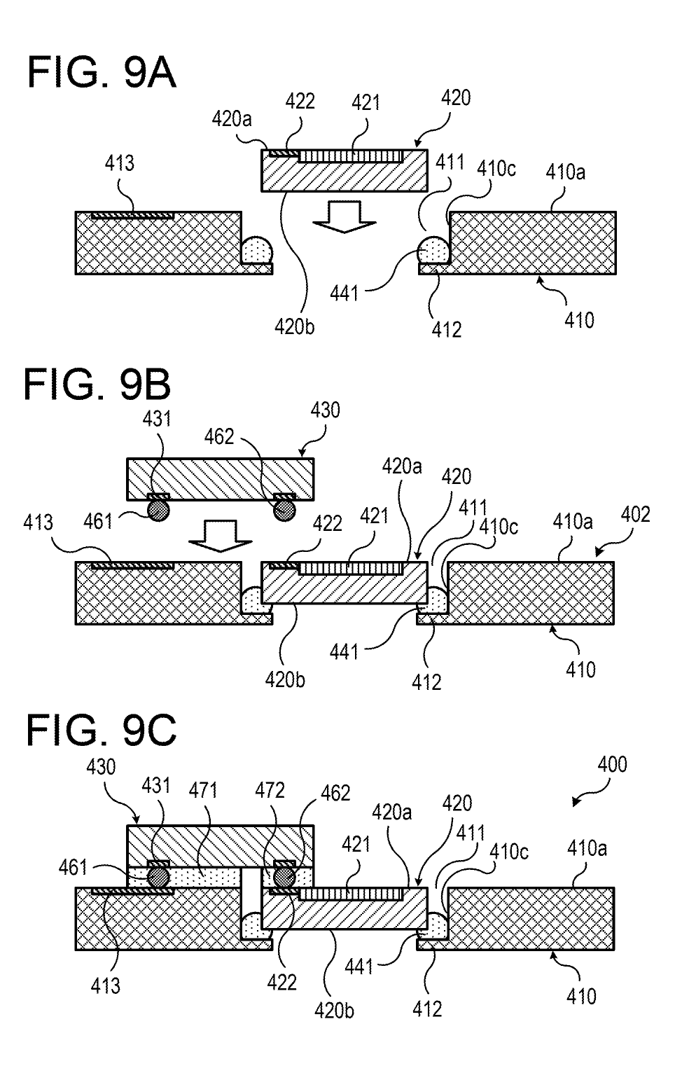

FIGS. 9A to 9C are views illustrating an example of a method of forming the board module according to the second embodiment. FIGS. 9A to 9C schematically illustrate main-part cross-sectional views of processes.

To form the board module 400, first, as illustrated in FIG. 9A, the circuit board 410 provided with the through hole 411 defined by the inner wall 410c having the protrusion 412 and the Si-Ph chip 420 disposed in the through hole 411 provided in the circuit board 410 are prepared. Further, the resin 441 is supplied onto the protrusion 412 provided on the prepared circuit board 410 by using a supply device such as a dispenser (nozzle) (not illustrated). The prepared Si-Ph chip 420 is inserted into the through hole 411 in which the resin 441 is supplied onto the protrusion 412.

The Si-Ph chip 420, which is inserted into the through hole 411, is controlled to a position at which the upper surface 420a of the Si-Ph chip 420 is positioned at a predetermined position with respect to the upper surface 410a of the circuit board 410, that is, for example, as illustrated in FIG. 9B, a position at which the upper surfaces 420a and 410a of the Si-Ph chip 420 and the circuit board 410 are positioned on the same plane. A method of controlling the upper surface 420a of the Si-Ph chip 420 to the predetermined position will be described below.

The resin 441 is cured in a state where the upper surface 420a of the Si-Ph chip 420 is controlled to the predetermined position. Therefore, as illustrated in FIG. 9B, a structure 402 in which the Si-Ph chip 420 is joined to the circuit board 410 by using the resin 441 is formed. As illustrated in FIG. 9B, the control chip 430, which is prepared by mounting the bumps 461 and 462 on the electrode 431, is mounted on the formed structure 402.

As illustrated in FIG. 9C, the control chip 430 is mounted above and across the circuit board 410 and the Si-Ph chip 420. The one bump 461 on the control chip 430 is joined to the circuit board 410, and the other bump 462 on the control chip 430 is joined to the Si-Ph chip 420, so that the control chip 430 is electrically and mechanically connected to the circuit board 410 and the Si-Ph chip 420.

Thereafter, as illustrated in FIG. 9C, the resin 471 is supplied between the control chip 430 and the circuit board 410 joined together by the bump 461, and the resin 472 is supplied between the control chip 430 and the Si-Ph chip 420 joined together by the bump 462, so that the connection between the control chip 430 and the circuit board 410 and the connection between the control chip 430 and the Si-Ph chip 420 are reinforced.

Although not illustrated, the heat dissipation member 450 (the connecting portion 451 of the heat dissipation member 450) is joined to the lower surface 420b of the Si-Ph chip 420 by using the TIM 442.

With this method, the board module 400 illustrated in the FIG. 8 is formed. In addition, a configuration before the heat dissipation member 450 is joined to the lower surface 420b of the Si-Ph chip 420 by using the TIM 442 may be obtained as the board module.

In the method illustrated in FIGS. 9A to 9C, the resin 441 is supplied onto the protrusion 412 provided on the circuit board 410, and the Si-Ph chip 420 inserted into the through hole 411 is joined to the protrusion 412 by using the resin 441. For this reason, even though the position precision of the through hole 411 provided in the circuit board 410 is not high, the problem described with reference to FIGS. 2E and 3B and caused by a variation of the width of the gap between the Si-Ph chip 420 and the inner wall 410c that defines the through hole 411, that is, interference with the nozzle, excess or deficiency of the resin 441, and drooping of the resin 441 may be suppressed. Therefore, it is possible to obtain the board module 400 having high quality.

In the method illustrated in FIGS. 9A to 9C, after the board module 400 having high quality is obtained, it is not necessary to form the through hole 411 in the circuit board 410 with high position precision, and it is not necessary to control the amount of the resin 441 in accordance with the width of the gap between the Si-Ph chip 420 and the inner wall 410c that defines the through hole 411. For this reason, it is possible to suppress an increase in manufacturing costs of the board module 400.

It is possible to reduce the number of processes in the method illustrated in FIGS. 9A to 9C in comparison with the method illustrated in FIGS. 2A to 2E. For this reason, it is possible to reduce manufacturing costs of the board module 400.

In the method illustrated in FIGS. 9A to 9C, the Si-Ph chip 420 is joined to the protrusion 412 provided on the circuit board 410 by using the resin 441, and then the control chip 430 is mounted above and across the circuit board 410 and the Si-Ph chip 420. For this reason, it is possible to suppress concentration of stress at the control chip 430 caused by the curing shrinkage of the resin 441, and damage to the control chip 430 caused by the concentration of stress, as described with reference to FIG. 2E.

According to the board module 400 having the configuration described above and the method of forming the board module 400, it is possible to implement the board module 400 having high quality with low costs.

Subsequently, a method of controlling the upper surface 420a of the Si-Ph chip 420 to the predetermined position in the board module 400 will be described.

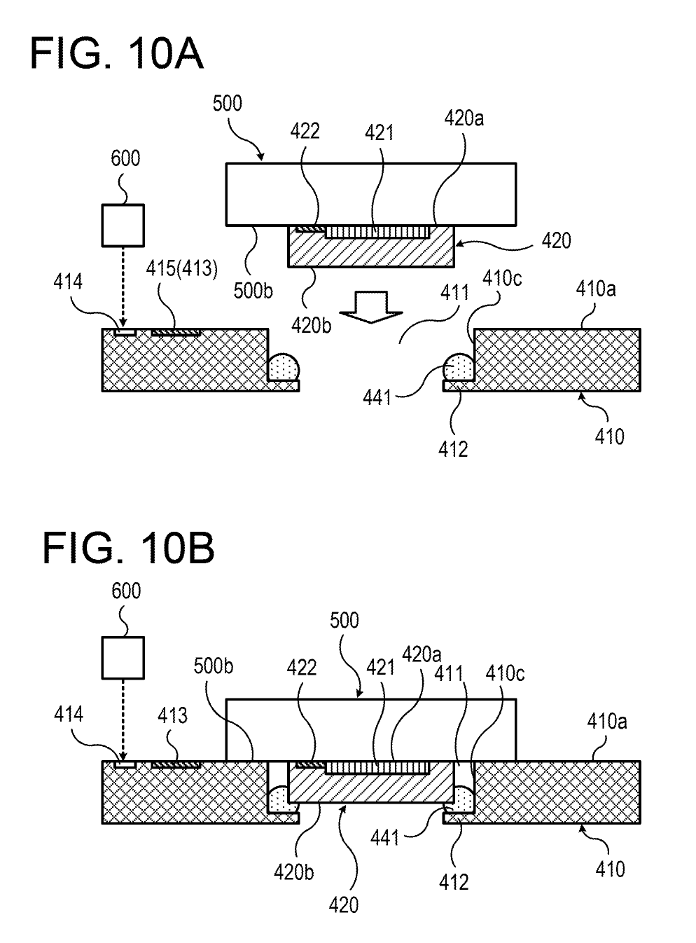

FIGS. 10A and 10B are explanatory views of a first example of chip position control according to the second embodiment. FIG. 10A schematically illustrates a main-part cross-sectional view in a state before the Si-Ph chip is joined, and FIG. 10B schematically illustrates a main-part cross-sectional view in a state while the Si-Ph chip is joined.

During the process of forming the board module 400 (FIG. 9A), as illustrated in FIG. 10A, the Si-Ph chip 420 is retained by a mounting tool 500 and inserted into the through hole 411 provided in the circuit board 410 in which the resin 441 is supplied onto the protrusion 412. The mounting tool 500, for example, attracts and retains the Si-Ph chip 420 and transfers the attracted and retained Si-Ph chip 420 into the through hole 411 provided in the circuit board 410. The mounting tool 500 has a lower surface 500b which is disposed at a side where the Si-Ph chip 420 is attracted and retained, and the lower surface 500b has a size larger in a plan view than a size of the through hole 411 into which the Si-Ph chip 420 is inserted.

A position of the mounting tool 500 in a height direction when the Si-Ph chip 420 is inserted into the through hole 411 is controlled by measuring, by using a camera 600, a distance from a mark 414 or a reference pad 415 provided on the upper surface 410a of the circuit board 410, and then providing feedback about the information to the mounting tool 500. For example, the wire 413 provided on the upper surface 410a of the circuit board 410 or a part of the wire 413 is used as the reference pad 415.

As illustrated in FIG. 10B, the Si-Ph chip 420 is inserted into the through hole 411 by the mounting tool 500, and the movement (downward movement) of the mounting tool 500 is stopped at a position at which the lower surface 500b of the mounting tool 500 is brought into contact with the upper surface 410a of the circuit board 410. In this way, the resin 441 is cured in a state where the lower surface 500b of the mounting tool 500 and the upper surface 410a of the circuit board 410 are brought into contact with each other. The resin 441 is cured by a method depending on the type of resin material used for the resin 441, for example, by heating or light irradiation. The mounting tool 500 may be provided with a mechanism for curing the resin 441 such as, for example, a heater for heating the resin 441 or a light source for irradiating the resin 441 with light. As the resin 441 is cured, the Si-Ph chip 420 is joined and fixed, by the resin 441, to the circuit board 410 (the protrusion 412 in the through hole 411 provided in the circuit board 410).

The resin 441 is cured in the state where the lower surface 500b of the mounting tool 500 and the upper surface 410a of the circuit board 410 are brought into contact with each other, and thus, as illustrated in FIG. 10B, the upper surfaces 420a and 410a of the Si-Ph chip 420 and the circuit board 410 are positioned on the same plane. Since the resin 441 is cured in the state where the lower surface 500b of the mounting tool 500, which retains the Si-Ph chip 420, is brought into contact with the upper surface 410a of the circuit board 410, it is possible to suppress a variation of the position of the Si-Ph chip 420 in the height direction even though the resin 441 experiences the curing shrinkage. In addition, the protrusion 412 are provided at the position below the lower surface 420b of the Si-Ph chip 420, that is, the position at which a margin is secured, so that the Si-Ph chip 420 and the protrusion 412 may be joined together via the resin 441.

The upper surface 420a of the Si-Ph chip 420 may not only be controlled to the position at which the upper surface 420a of the Si-Ph chip 420 and the upper surface 410a of the circuit board 410 are positioned on the same plane, but also be controlled to a position either above or below the upper surface 410a of the circuit board 410.

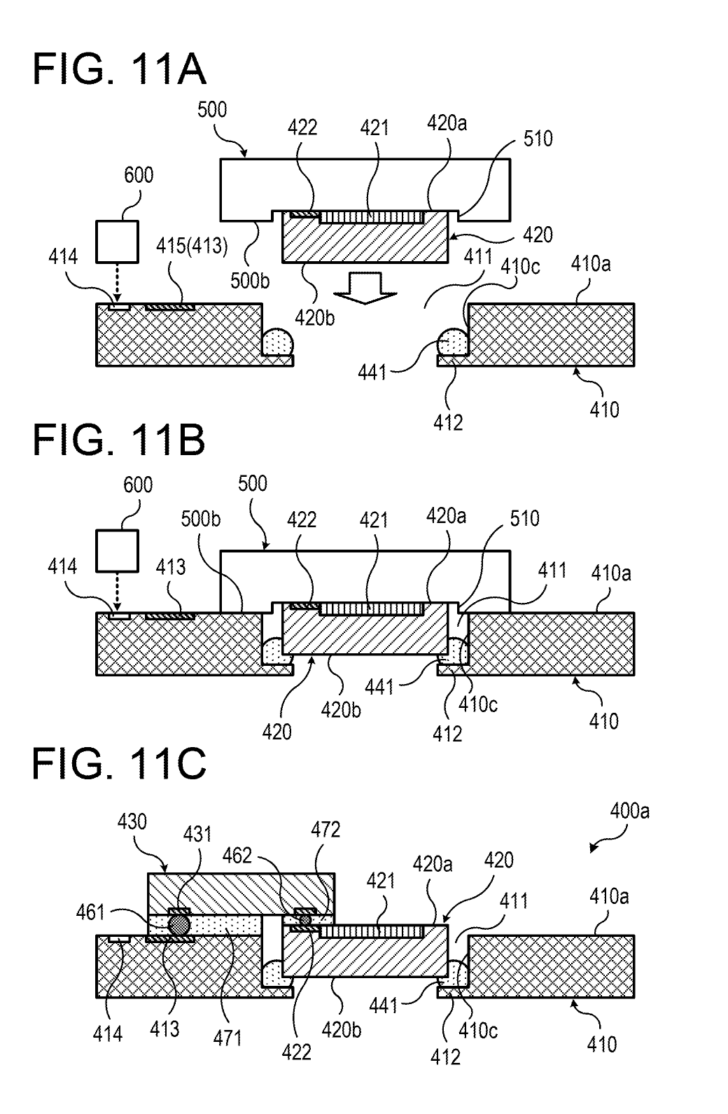

FIGS. 11A to 11C are explanatory views of a second example of the chip position control according to the second embodiment. FIG. 11A schematically illustrates a main-part cross-sectional view in a state before the Si-Ph chip is joined, FIG. 11B schematically illustrates a main-part cross-sectional view in a state while the Si-Ph chip is joined, and FIG. 11C schematically illustrates a main-part cross-sectional view in a state after the control chip is mounted.

In this example, as illustrated in FIG. 11A, a concave portion 510 recessed inward from the lower surface 500b is provided in the mounting tool 500, and the Si-Ph chip 420 is attracted and retained in the concave portion 510.

The camera 600 and the mark 414 or the reference pad 415 (the wire 413 or a part of the wire 413) are used, and the mounting tool 500, which attracts and retains the Si-Ph chip 420, is moved to the position at which the lower surface 500b of the mounting tool 500 is brought into contact with the upper surface 410a of the circuit board 410, as illustrated in FIG. 11B. As the resin 441 is cured in this state, the Si-Ph chip 420 is joined and fixed, by the resin 441, to the circuit board 410 (the protrusion 412 in the through hole 411 provided in the circuit board 410). Since the Si-Ph chip 420 is attracted and retained in the concave portion 510 of the mounting tool 500, the upper surface 420a of the Si-Ph chip 420 is positioned above the upper surface 410a of the circuit board 410 when the resin 441 is cured and joined.

As illustrated in FIG. 11C, the control chip 430 is mounted above and across the circuit board 410 and the Si-Ph chip 420. In this case, the control chip 430 having the bump 462, which is connected to the Si-Ph chip 420 and has a size (diameter or height) smaller than a size (diameter or height) of the bump 461 connected to the circuit board 410, is mounted on the circuit board 410 and the Si-Ph chip 420. Therefore, a board module 400a illustrated in FIG. 11C is obtained. The control chip 430, on which the bump 462 having a size smaller than a size of the bump 461 is mounted, may be precisely mounted while suppressing a joint defect, by positioning the upper surface 420a of the Si-Ph chip 420 above the upper surface 410a of the circuit board 410.

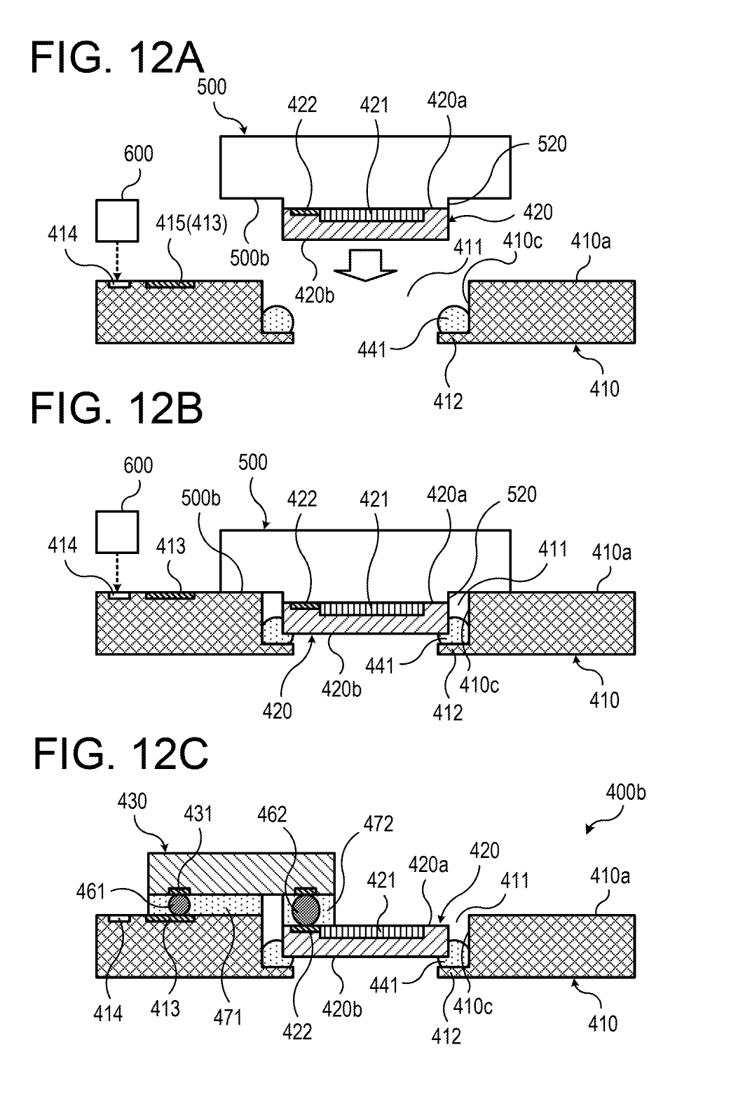

FIGS. 12A to 12C are explanatory views of a third example of the chip position control according to the second embodiment. FIG. 12A schematically illustrates a main-part cross-sectional view in a state before the Si-Ph chip is joined, FIG. 12B schematically illustrates a main-part cross-sectional view in a state while the Si-Ph chip is joined, and FIG. 12C schematically illustrates a main-part cross-sectional view in a state after the control chip is mounted.

In this example, as illustrated in FIG. 12A, a convex portion 520 protruding outward from the lower surface 500b is provided on the mounting tool 500, and the Si-Ph chip 420 is attracted and retained on the convex portion 520.

The camera 600 and the mark 414 or the reference pad 415 (the wire 413 or a part of the wire 413) are used, and the mounting tool 500, which attracts and retains the Si-Ph chip 420, is moved to the position at which the lower surface 500b of the mounting tool 500 is brought into contact with the upper surface 410a of the circuit board 410, as illustrated in FIG. 12B. As the resin 441 is cured in this state, the Si-Ph chip 420 is joined and fixed, by the resin 441, to the circuit board 410 (the protrusion 412 in the through hole 411 provided in the circuit board 410). Since the Si-Ph chip 420 is attracted and retained on the convex portion 520 of the mounting tool 500, the upper surface 420a of the Si-Ph chip 420 is positioned below the upper surface 410a of the circuit board 410 when the resin 441 is cured and joined.

As illustrated in FIG. 12C, the control chip 430 is mounted above and across the circuit board 410 and the Si-Ph chip 420. In this case, the control chip 430 having the bump 462, which is connected to the Si-Ph chip 420 and has a size (diameter or height) larger than a size (diameter or height) of the bump 461 connected to the circuit board 410, is mounted on the circuit board 410 and the Si-Ph chip 420. Therefore, a board module 400b illustrated in FIG. 12C is obtained. The control chip 430, on which the bump 462 having a size larger than a size of the bump 461 is mounted, may be precisely mounted while suppressing a joint defect, by positioning the upper surface 420a of the Si-Ph chip 420 below the upper surface 410a of the circuit board 410.

To form the board module 400a or 400b on which the control chip 430 having the bumps 461 and 462 with different sizes is mounted, a depth of the concave portion 510 or a height of the convex portion 520 from the lower surface 500b of the mounting tool 500 is adjusted in accordance with a difference in size between the bumps 461 and 462.

Subsequently, a configuration of the protrusion 412 provided on the circuit board 410 will be described.

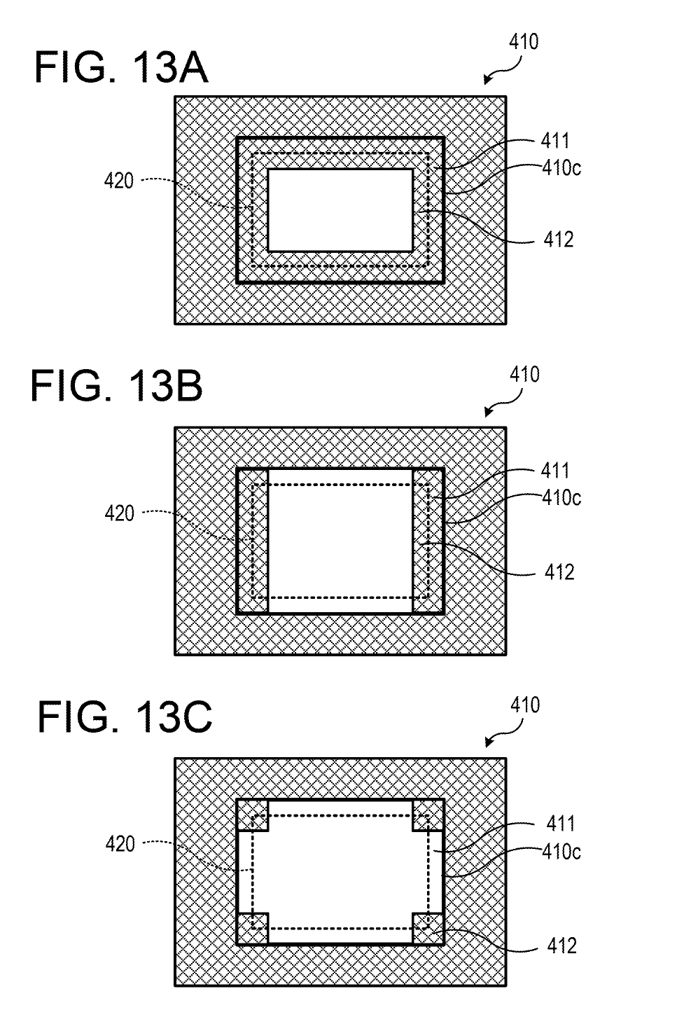

FIGS. 13A to 13C are views illustrating a configuration example of the circuit board according to the second embodiment. FIGS. 13A to 13C schematically illustrate a main-part top plan view of an example of the circuit board.

For example, as illustrated in FIG. 13A, the protrusion 412, which is continuously formed along the entire circumference of the inner wall 410c that defines the through hole 411 in which the Si-Ph chip 420 (indicated by a dotted line in FIG. 13A) is disposed, may be provided on the circuit board 410.

Additionally, for example, as illustrated in FIG. 13B, two protrusions 412 may be formed on the circuit board 410 along facing portions of the inner wall 410c that defines the through hole 411 in which the Si-Ph chip 420 (indicated by a dotted line in FIG. 13B) is disposed.

Alternatively, for example, as illustrated in FIG. 13C, four protrusions 412, which are formed at four corners of the inner wall 410 that defines the through hole 411 in which the Si-Ph chip 420 (indicated by a dotted line in FIG. 13C) is disposed, may be provided on the circuit board 410.

The protrusion 412, which has various types of shapes in a plan view and are variously disposed in a plan view, may be provided on the circuit board 410 so that the Si-Ph chip 420 may be joined to the protrusion 412 by using the resin 441.

In the board module 400 or the like, a joint area between the Si-Ph chip 420 disposed in the through hole 411 and the heat dissipation member 450 disposed on the lower surface 420b of the Si-Ph chip 420 via the TIM 442 may be adjusted in accordance with the shape and the disposition in a plan view of the protrusion 412 provided on the circuit board 410.

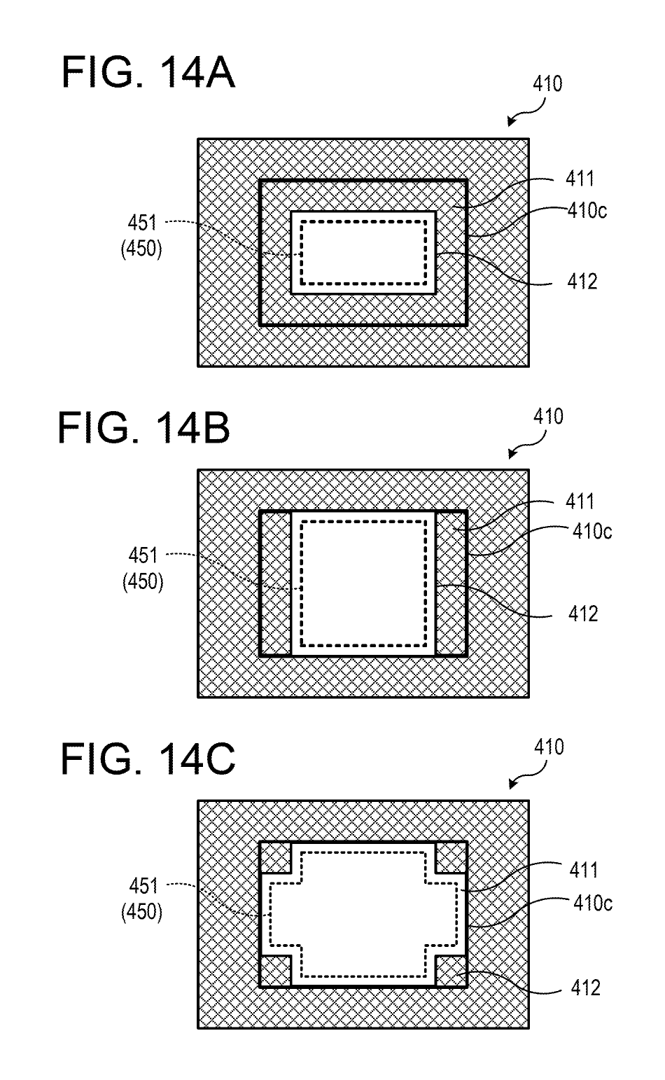

FIGS. 14A to 14C are explanatory views of a positional relationship between the protrusion provided on the circuit board according to the second embodiment and the connecting portion of the heat dissipation member. FIGS. 14A to 14C schematically illustrate a main-part top plan view of an example of the circuit board.

FIG. 14A illustrates an example of the circuit board 410 on which the protrusion 412 is provided along the entire circumference of the inner wall 410c that defines the through hole 411, as described with reference to FIG. 13A. In the case of the example illustrated in FIG. 14A, the connecting portion 451 (indicated by a dotted line in FIG. 14A) of the heat dissipation member 450 connected to the lower surface 420b of the Si-Ph chip 420 (indicated by a dotted line in FIG. 13A) via the TIM 442 has a size in a plan view which is accommodated in a region surrounded by the protrusion 412 formed along the entire circumference.

FIG. 14B illustrates an example of the circuit board 410 on which two protrusions 412 are provided along the facing portions of the inner wall 410c that defines the through hole 411, as described with reference to FIG. 13B. In the case of the example illustrated in FIG. 14B, the connecting portion 451 (indicated by a dotted line in FIG. 14B) of the heat dissipation member 450 has a size in a plan view which is accommodated in a region between the facing protrusions 412 and surrounded by portions of the inner wall 410c which have no protrusion 412 and face each other. In the example illustrated in FIG. 14B, since there are the portions having no protrusion 412 in the through hole 411, it is possible to increase a size in a plan view of the connecting portion 451 of the heat dissipation member 450 in comparison with the example illustrated in FIG. 14A in which the protrusion 412 is provided along the entire circumference. By increasing the size in a plan view of the connecting portion 451, it is possible to increase a joint area (heat transfer area) with the Si-Ph chip 420 via the TIM 442, and it is possible to improve efficiency in transferring heat from the Si-Ph chip 420 to the heat dissipation member 450.

FIG. 14C illustrates an example of the circuit board 410 on which four protrusions 412 are provided at the four corners of the inner wall 410c that defines the through hole 411, as described with reference to FIG. 13C. In the case of the example illustrated in FIG. 14C, the connecting portion 451 (indicated by a dotted line in FIG. 14C) of the heat dissipation member 450 has a size in a plan view which is accommodated in a region surrounded by the protrusions 412 at the four corners and portions between the protrusions 412. In the example illustrated in FIG. 14C, it is possible to increase a size in a plan view of the connecting portion 451 of the heat dissipation member 450 in comparison with the example illustrated in FIG. 14A in which the protrusion 412 is provided along the entire circumference and the example illustrated in FIG. 14B in which two protrusions 412 are provided along the facing portions of the inner wall 410c. By increasing the size in a plan view of the connecting portion 451, it is possible to increase a joint area (heat transfer area) with the Si-Ph chip 420 via the TIM 442, and it is possible to improve efficiency in transferring heat from the Si-Ph chip 420 to the heat dissipation member 450.

### Third Embodiment

Next, a third embodiment will be described. Here, a modified example of the board module 400 will be described as a third embodiment.

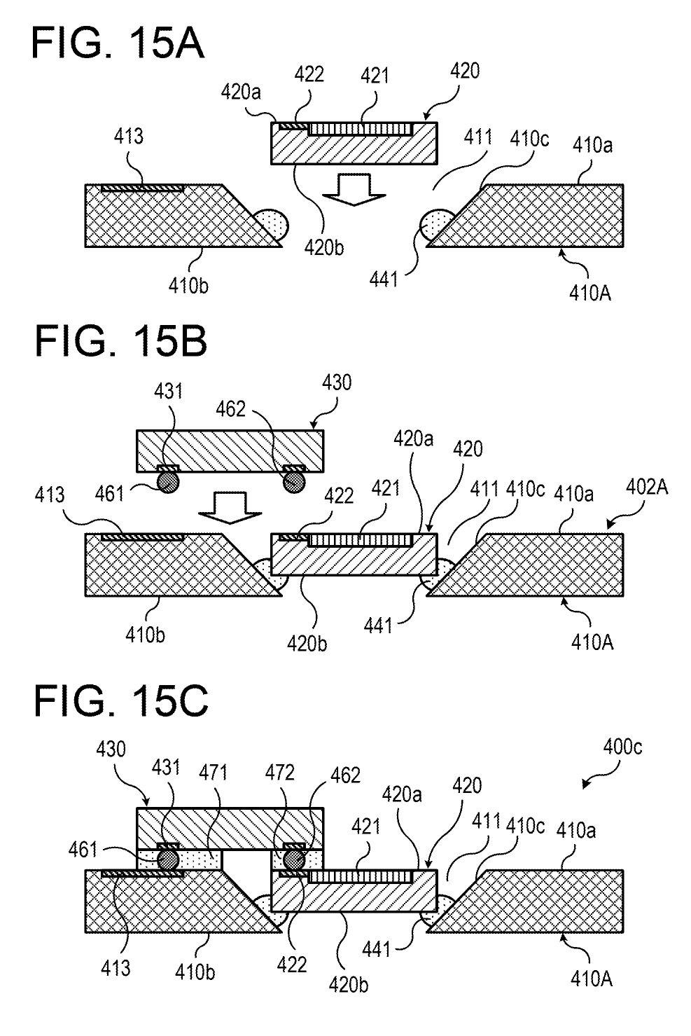

FIGS. 15A to 15C are views illustrating a first example of a method of forming a board module according to a third embodiment. FIGS. 15A to 15C schematically illustrate main-part cross-sectional views of processes.

In this example, as illustrated in FIG. 15A, a circuit board 410A provided with a through hole 411 defined by an inner wall 410c inclined from an upper surface 410a toward a lower surface 410b, is prepared. An opening size of the through hole 411 at the side of the upper surface 410a is a size that enables the Si-Ph chip 420 to be inserted into the through hole 411, and an opening size of the through hole 411 at the side of the lower surface 410b is a size that does not permit the inserted Si-Ph chip 420 to pass therethrough.

The entire circumference of the inner wall 410c, which defines the through hole 411, need not necessarily be formed in a shape inclined as illustrated in FIG. 15A. For example, facing portions of the inner wall 410c, a part of the inner wall 410c, four corners of the inner wall 410c or the like may be formed in a shape inclined as illustrated in FIG. 15A.

The inner wall 410c, which defines the through hole 411, need not necessarily be formed in a shape inclined rectilinearly in a cross-sectional view as illustrated in FIG. 15A. For example, the inner wall 410c, which defines the through hole 411, may be formed in a shape, for example, inclined in a convex shape, a concave shape, or a wave shape in a cross-sectional view.

The through hole 411 provided in the circuit board 410A may be called the through hole 411 defined by the inner wall 410c having the protrusion.

The Si-Ph chip 420, which is to be disposed in the through hole 411 provided in the circuit board 410A, as illustrated in FIG. 15A, is prepared together with the circuit board 410A. Further, the resin 441 is supplied, by using a supply device such as a dispenser (nozzle) (not illustrated), onto the inclined inner wall 410c that defines the through hole 411 provided in the circuit board 410A. The resin 441 having comparatively high viscosity is used, and as a result, it is possible to suppress the resin 441, which is supplied onto the inclined inner wall 410c that defines the through hole 411, from drooping toward the lower surface 410b. The viscosity of the resin 441 may be adjusted in accordance with a component of resin and types or amounts of additives or fillers. The Si-Ph chip 420 is inserted into the through hole 411 to which the resin 441 is supplied.

The Si-Ph chip 420, which is inserted into the through hole 411, is controlled to a position at which the upper surface 420a of the Si-Ph chip 420 is positioned at a predetermined position with respect to the upper surface 410a of the circuit board 410A, that is, for example, as illustrated in FIG. 15B, a position at which the upper surfaces 420a and 410a are positioned on the same plane. The position control of the Si-Ph chip 420 with respect to the circuit board 410A may be performed by using the mounting tool 500, as described with reference to FIGS. 10A to 12C. The resin 441 is cured in the state where the upper surface 420a of the Si-Ph chip 420 is controlled to the predetermined position. Therefore, a structure 402A in which the Si-Ph chip 420 is joined to the circuit board 410A by using the resin 441 is formed.

By the adjustment of viscosity of the resin 441 to be supplied and the position control using the mounting tool 500, even in the case of the circuit board 410A having the through hole 411 illustrated in FIG. 15B, it is possible to retain the Si-Ph chip 420 at the predetermined position and fix the Si-Ph chip 420 in the through hole 411 by curing the resin 441.

As illustrated in FIG. 15B, the control chip 430, which is prepared by mounting the bumps 461 and 462 on the electrode 431, is mounted on the formed structure 402A. As illustrated in FIG. 15C, the control chip 430 is mounted above and across the circuit board 410A and the Si-Ph chip 420. The one bump 461 on the control chip 430 is joined to the wire 413 of the circuit board 410A, and the other bump 462 on the control chip 430 is joined to the wire 422 of the Si-Ph chip 420. Thereafter, as illustrated in FIG. 15C, the resin 471 is supplied between the control chip 430 and the circuit board 410A joined together by the bump 461, and the resin 472 is supplied between the control chip 430 and the Si-Ph chip 420 joined together by the bump 462.

With this method, a board module 400c illustrated in the FIG. 15C is formed.

Although not illustrated, the heat dissipation member 450 (the connecting portion 451 of the heat dissipation member 450) may be joined to the lower surface 420b of the Si-Ph chip 420 by using the TIM 442. The configuration in which the heat dissipation member 450 is joined to the lower surface 420b of the Si-Ph chip 420 of the board module 400c by using the TIM 442 may be obtained as the board module.

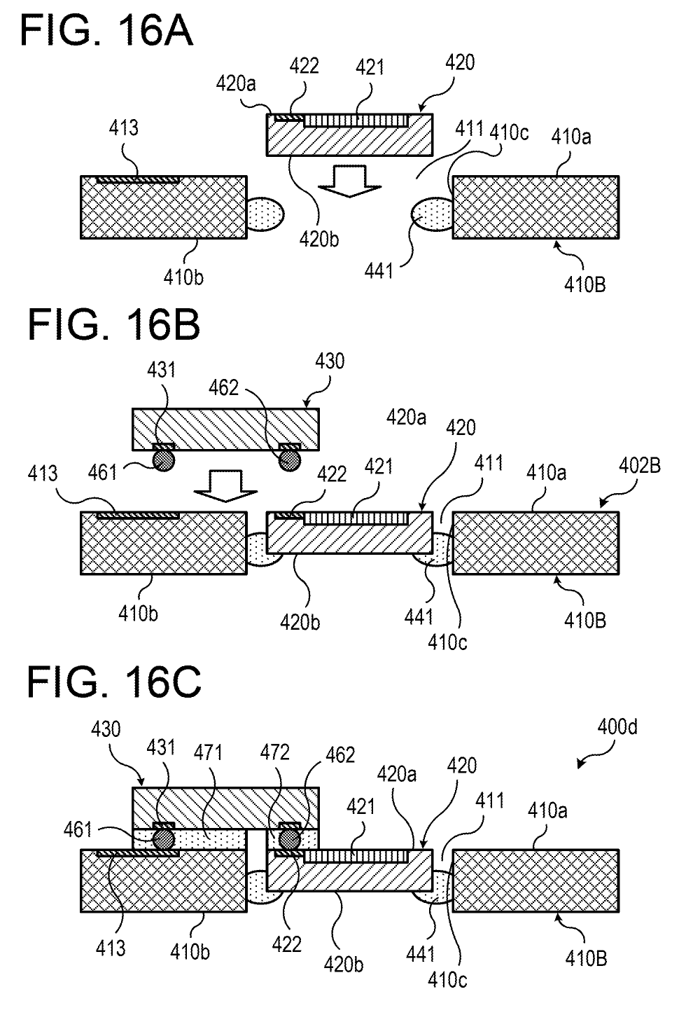

FIGS. 16A to 16C are views illustrating a second example of the method of forming the board module according to the third embodiment. FIGS. 16A to 16C schematically illustrate main-part cross-sectional views of processes.

In this example, a circuit board 410B provided with a through hole 411 illustrated in FIG. 16A is prepared. Opening sizes of the through hole 411 at the side of the upper surface 410a and the side of the lower surface 410b are equal or substantially equal to each other and are sizes that enable the Si-Ph chip 420 to be inserted into the through hole 411.

The Si-Ph chip 420, which is to be disposed in the through hole 411 provided in the circuit board 410B, as illustrated in FIG. 16A, is prepared together with the circuit board 410B. Further, the resin 441 is supplied, by using a supply device such as a dispenser (nozzle) (not illustrated), onto the inner wall 410c that defines the through hole 411 provided in the circuit board 410B. The resin 441 having comparatively high viscosity is used, and as a result, it is possible to suppress the resin 441, which is supplied onto the inner wall 410c that defines the through hole 411, from drooping toward the lower surface 410b. The viscosity of the resin 441 may be adjusted in accordance with a component of resin and types or amounts of additives or fillers. The Si-Ph chip 420 is inserted into the through hole 411 to which the resin 441 is supplied.

The Si-Ph chip 420, which is inserted into the through hole 411, is controlled to a position at which the upper surface 420a of the Si-Ph chip 420 is positioned at a predetermined position with respect to the upper surface 410a of the circuit board 410B, that is, for example, as illustrated in FIG. 16B, a position at which the upper surfaces 420a and 410a are positioned on the same plane. The position control of the Si-Ph chip 420 with respect to the circuit board 410B may be performed by using the mounting tool 500, as described with reference to FIGS. 10A to 12C. The resin 441 is cured in the state where the upper surface 420a of the Si-Ph chip 420 is controlled to the predetermined position. Therefore, a structure 402B in which the Si-Ph chip 420 is joined to the circuit board 410B by using the resin 441 is formed.

By the adjustment of viscosity of the resin 441 to be supplied and the position control using the mounting tool 500, even in the case of the circuit board 410B having the through hole 411 illustrated in FIG. 16B, it is possible to retain the Si-Ph chip 420 at the predetermined position and fix the Si-Ph chip 420 in the through hole 411 by curing the resin 441.

As illustrated in FIG. 16B, the control chip 430, which is prepared by mounting the bumps 461 and 462 on the electrode 431, is mounted on the formed structure 402B. As illustrated in FIG. 16C, the control chip 430 is mounted above and across the circuit board 410B and the Si-Ph chip 420. The one bump 461 on the control chip 430 is joined to the wire 413 of the circuit board 410B, and the other bump 462 on the control chip 430 is joined to the wire 422 of the Si-Ph chip 420. Thereafter, as illustrated in FIG. 16C, the resin 471 is supplied between the control chip 430 and the circuit board 410B joined together by the bump 461, and the resin 472 is supplied between the control chip 430 and the Si-Ph chip 420 joined together by the bump 462.

With this method, a board module 400d illustrated in the FIG. 16C is formed.

Although not illustrated, the heat dissipation member 450 (the connecting portion 451 of the heat dissipation member 450) may be joined to the lower surface 420b of the Si-Ph chip 420 by using the TIM 442. The configuration in which the heat dissipation member 450 is joined to the lower surface 420b of the Si-Ph chip 420 of the board module 400d by using the TIM 442 may be obtained as the board module.

All examples and conditional language recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority and inferiority of the disclosure. Although the embodiments of the present disclosure have been described in detail, it should be understood that the various changes, substitutions, and alterations could be made hereto without departing from the spirit and scope of the disclosure.

What is claimed is:

1. A board module comprising:
a first board having an inner wall that has a protrusion and defines a through hole;
a second board provided in the through hole and joined to the protrusion by using a resin; and
a third board joined above and across the first board and the second board.

2. The board module according to claim 1, wherein
the first board includes a first wire,
the second board includes an optical element and a second wire electrically connected to the optical element, and
the third board includes a first electrode electrically connected to the first wire, and a second electrode electrically connected to the second wire.

3. The board module according to claim 2, further comprising:
a first joint portion provided between the first board and the third board and configured to join the first wire and the first electrode; and
a second joint portion provided between the second board and the third board and configured to join the second wire and the second electrode.

4. The board module according to claim 2, further comprising:
a component optically connected to the optical element.

5. The board module according to claim 1, further comprising:
a heat dissipation member thermally connected to the second board below the second board.

6. The board module according to claim 1, wherein
an upper surface of the first board and an upper surface of the second board are positioned on a same plane.

7. The board module according to claim 1, wherein
an upper surface of the second board is positioned either above or below an upper surface of the first board.

8. The board module according to claim 1, further comprising:
a casing configured to accommodate the first board, the second board, and the third board.

9. A method of manufacturing a board module, the method comprising:
providing a resin onto a protrusion of an inner wall of a first board, wherein the inner wall defines a through hole;
inserting a second board into the through hole and joining the second board to the protrusion by using the resin; and
joining a third board above and across the first board and the second board.

10. The method according to claim 9, wherein
the inserting of the second board into the through hole includes:
retaining the second board by using a mounting tool and transferring the second board into the through hole; and
controlling an upper surface of the second board to a predetermined position with respect to an upper surface of the first board by bringing a surface of the mounting tool into contact with the upper surface of the first board, wherein, the surface of the mounting tool retains the second board.

11. A method of manufacturing a board module, the method comprising:
providing a resin onto an inner wall of a first board, wherein the inner wall defines a through hole;
inserting a second board into the through hole and joining the second board to the inner wall by using the resin; and
joining a third board above and across the first board and the second board.

12. The method according to claim 11, wherein
the inserting of the second board into the through hole includes:
retaining the second board by using a mounting tool and transferring the second board into the through hole; and
controlling an upper surface of the second board to a predetermined position with respect to an upper surface of the first board by bringing a surface of the mounting tool into contact with the upper surface of the first board, wherein, the surface of the mounting tool retains the second board.
